(19) United States
(12) Patent Application Publication
(10) Pub. No.: US 2026/0133225 A1
(43) Pub. Date: May 14, 2026

(54) CURRENT SENSING CIRCUIT

(71) Applicant: Renesas Design (UK) Limited, Bourne End (GB)

(72) Inventors: Chien-Liang CHEN, San Jose, CA (US); Yu RONG, San Jose, CA (US); Yimin CHEN, San Jose, CA (US); Guang FENG, San Jose, CA (US)

(73) Assignee: Renesas Design (UK) Limited, Bourne End (GB)

(21) Appl. No.: 18/947,387

(22) Filed: Nov. 14, 2024

(51) Int. Cl. G01R 1/20; H02M 1/32; H03K 17/0812

(52) U.S. Cl. CPC G01R 1/203; H02M 1/32; H03K 17/0812; H03K 2217/0027

(57) ABSTRACT

A current sensing circuit including: a current sensing, CS, pin; a first switch; a second switch, wherein the second switch is connected between the first switch and ground; a plurality of resistors connected between the second switch and ground; and a resonant circuit; wherein the plurality of resistors is configured to detect positive and/or negative over-currents in the CS pin.

### FIELD

The present disclosure relates to negative overcurrent detection and protection for a current conversion circuit.

### BACKGROUND

Typically, overcurrent detection is designed for protection when there is a large positive current, such as can arise in current conversion circuits. An existing circuit designed for this purpose is illustrated by FIG. 1 which shows a sensing resistor, Rsns, connected between the source of a switch, S2, and ground, GND. When another switch, S1, is turned on and S2 is turned off, a current, iLr, passing through the inductors Lr and Lm increases such that it can be detected, by current sensing, CS, pin, through the voltage across the sensing resister, Rsns.

By setting an overcurrent protection, OCP, comparator threshold value, large positive iLr currents may be detected in the event of: an S1 false turn on (that is, when a digital switching pattern would have S1 turned off but some fault has caused it to turn on), an S1 and S2 shoot through current, or an S1 and synchronous rectification, SR, shoot through current.

When such an overcurrent is detected, both S1 and S2 may be forced off to protect the circuit. However, the simple current sensing structure of FIG. 1 cannot detect large negative resonant currents such as that shown in FIG. 2, which represents the circuit of FIG. 1 experiencing a large negative resonant current, iLr.

In the case of a large negative current, the configuration does not allow the CS pin to receive information indicating the large negative current.

Another prior art example is depicted in FIG. 2, wherein the sensing resistor Rsns is connected between the capacitor Cr and the ground, GND. This circuit allows both positive and negative resonant currents to be detected though the voltage across the sensing resistor Rsns. However, this circuit leads to significant power loss across the resistor Rsns because it is required to conduct current constantly during converter switching. In addition, it is not configured to be able to detect large currents or over-currents when S1 and S2 shoot through currents are experienced.

Thus, an alternative approach is required to provide a circuit which is able to detect negative overcurrent and protect against negative overcurrent with reduced power loss on the sensing resistors.

### SUMMARY

According to a first aspect of the disclosure, there is provided a current conversion circuit comprising: a current sensing, CS, pin; a first switch; a second switch, wherein the second switch is connected between the first switch and ground; a plurality of resistors connected between the second switch and ground; and a resonant circuit;
wherein the plurality of resistors is configured to detect positive and/or negative over-currents in the CS pin.

Optionally, wherein detecting the positive and/or negative over-currents comprises: detecting if a voltage across the CS pin is lower than a negative threshold; and/or detecting if a voltage across the CS pin is higher than a positive threshold.

Optionally, wherein when it is detected that the voltage across the CS pin is lower than the negative threshold, it is determined that there is a negative over-current and the second switch is turned off.

Optionally, wherein when a positive or negative over-current is detected, the first switch and the second switch are controlled to turn off.

Optionally, wherein the resonant circuit comprises: an inductor and a capacitor; or an inductor.

The inductor may instead be a transformer.

Optionally, wherein the plurality of resistors comprises: first and second sensor resistors; and first and second configuration resistors.

Optionally, wherein a CS pin voltage, Vcs, applied to the CS pin is defined by:

$${V}_{cs} = {V}_{a} + k \cdot {V}_{b} ;$$

wherein Va is a voltage across the first sensor resistor;
wherein Vb is voltage across the second sensor resistor;
wherein k is a ratio of resistance values of the first and second configuration resistors.

Optionally, wherein when the first switch is turned on and the second switch is turned off, an effective sensing resistance for the current sensing circuit is:

$${R}_{sns \_ MS} = {R}_{a} + k \cdot {R}_{b} ;$$

wherein Ra is a resistance of the first sensor resistor; and
wherein Rb is a resistance of the second sensor resistor.

Optionally, wherein when the second switch is turned on and the first switch is turned off, an effective sensing resistance for the current sensing circuit is:

$${R}_{sns \_ RS} = k \cdot {R}_{b} ;$$

wherein Rb is a resistance of the second sensor resistor.

Optionally, wherein when the first switch is turned on and the second switch is turned off:
a first voltage across the first sensor resistor, Vₐ=i_{Lr}·Rₐ;
a second voltage across the second sensor resistor, V_{b}=i_{Lr}; and
a CS voltage across the CS pin, V_{CS}=i_{Lr}·(Rₐ+k·R_{b});
wherein i_{Lr} is the resonant current.

Optionally, wherein when the second switch is turned on and the first switch is turned off:
the first voltage across the first sensor resistor, Vₐ=0;
the second voltage across the second sensor resistor, V_{b}=i_{Lr}·R_{b}; and
the CS voltage across the CS pin, V_{CS}=i_{Lr}·k·R_{b}.

Optionally, wherein when both the second switch and the first switch are turned on:
the first voltage across the first sensor resistor, Vₐ=i_{Lr}·Rₐ;
the second voltage across the second sensor resistor, V_{b}=i_{Lr}·R_{b}; and
the CS voltage across the CS pin, V_{CS}=iₛₕ·Rₐ+i_{Lr}·k·R_{b};
   wherein iₛₕ is a shoot through current passing through the first switch and the second switch.

Optionally, wherein

$$k = \frac{{R}_{ca}}{{R}_{ca} + {R}_{cb}} ;$$

wherein Rca is a resistance of the first configuration resistor; and
wherein Rcb is a resistance of the second configuration resistor.

Optionally, wherein k is selected based on power loss values and a shoot through current, iₛₕ, value variations.

Optionally, wherein the first configuration resistor and the second sensor resistor are connected in series; wherein the first configuration resistor and the second sensor resistor are connected in parallel with the second configuration resistor; and wherein the first sensor resistor is connected in series with the first switch and the second switch.

Optionally, wherein when the first switch and the second switch are both turned on, a current path through the first switch, the second switch, and the first sensor resistor to ground is created.

Optionally, wherein resistance values of the first configuration resistor and the second configuration resistor are selected to provide an effective configuration resistance for the CS pin.

Optionally, wherein the first switch is a mains switch; and wherein the second switch is a resistor switch.

Optionally, wherein k is a value between 0 and 1.

According to a second aspect of the disclosure there is provided a method of operating the current sensing circuit, the method comprising: detecting, by the plurality of resistors, a positive and/or negative over-current in the current sensing, CS, pin.

### BRIEF DESCRIPTION OF THE DRAWINGS

The disclosure is described in further detail below by way of example and with reference to the accompanying drawings, in which:

FIGS. 1A and 1B show a circuit diagram according to the prior art;

FIG. 2 shows a circuit diagram according to the prior art;

FIG. 3 shows a circuit diagram according to the prior art;

FIG. 4 shows a block diagram representing a current sensing circuit;

FIGS. 5A and 5B show a circuit diagrams representing an operation mechanism of a current sensing circuit; and

FIG. 6 shows graphs illustrating a comparison between the prior art and the current disclosure.

### DETAILED DESCRIPTION

The present disclosure relates to a novel negative resonant current protection circuit for half bridge or full bridge resonant power converters (such as asymmetrical half bridge, AHB, converters). Conventionally, overcurrent protection, OCP, is designed for large positive current protection. However, large negative current is also possible for resonant power converters. Thus, large negative OCP is also required to protect a power converter from overcurrent damage.

In more detail, in the case that the resonant power converter is turned on for a long time, and thus a main switch of the power conversion circuit is also on for a long time, a large voltage is charged across a capacitor of the circuit. This large voltage will cause a large negative resonant current when the reset switch is on. This large negative resonant current heats up the reset switch, damaging the device. Thus, it is desirable to limit the negative resonant current using overcurrent protection.

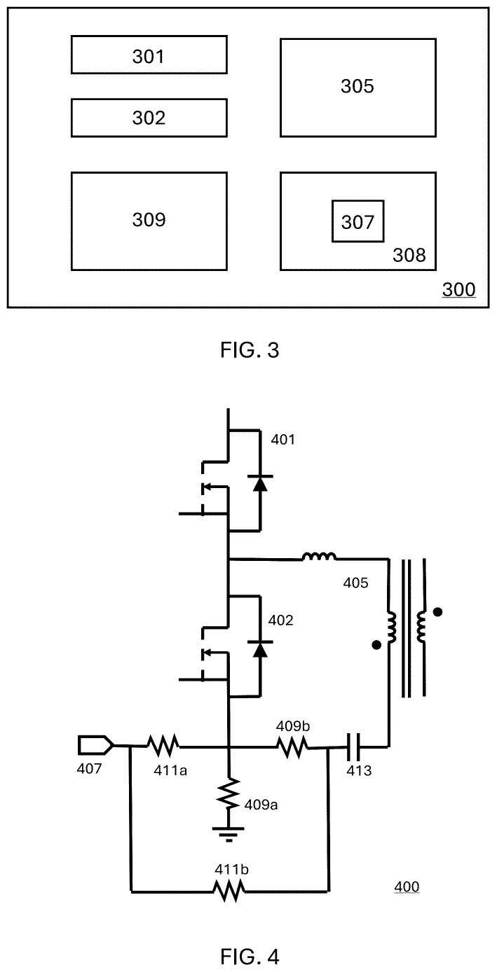

FIG. 3 is a block diagram representing a current conversion circuit. The current conversion circuit comprises a current sensing, CS, pin 307; a first switch 301; a second switch 302; a resonant circuit 305 and a plurality of resistors 309.

The CS pin may be part of an integrated circuit 308.

The resonant circuit 305 may comprise an inductor or transformer (such as a resonant inductor) and a capacitor. Alternatively, the resonant circuit 305 may comprise an inductor or transformer (such as a resonant inductor) alone. Alternatively, for both of these examples, the inductor may instead be a transformer.

The first switch 301 and the second switch 302 may be any kind of switching device.

The plurality of resistors 309 is configured to detect positive and/or negative over-currents in the CS pin. The plurality of resistors 309 may include sensor resistors and configuration resistors.

FIG. 4 shows a circuit diagram illustrating to a current conversion circuit 400 such as the circuit represented by FIG. 4.

The current conversion circuit 400 comprises a current sensing, CS, pin 407; a first switch 401; and second switch 402, wherein the second switch is connected between the first switch and ground, GND; a plurality of resistors 409a, 409b, 411a, 411b connected between the second switch 402 and ground and a resonant circuit; wherein the plurality of resistors 409a, 409b, 411a, 411b is configured to detect positive and/or negative over-currents in the CS pin 407.

The plurality of resistors 409a, 409b, 411a, 411b may comprise first 409a and second 409b sensor resistors; and first 411a and second 411b configuration resistors. The plurality of resistors 409a, 409b, 411a, 411b may be any kind of resistive device. For example, any kind of resistor may be used.

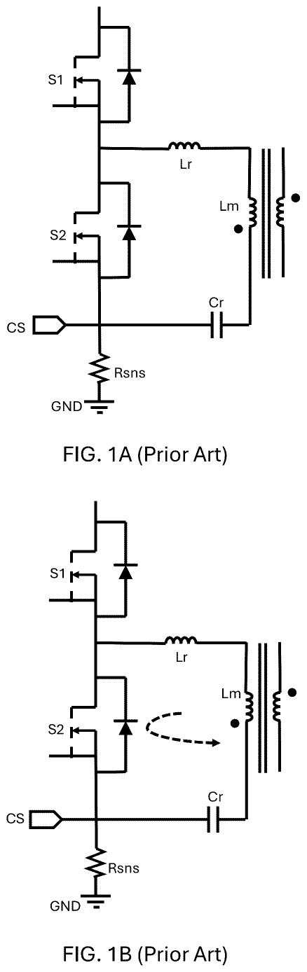

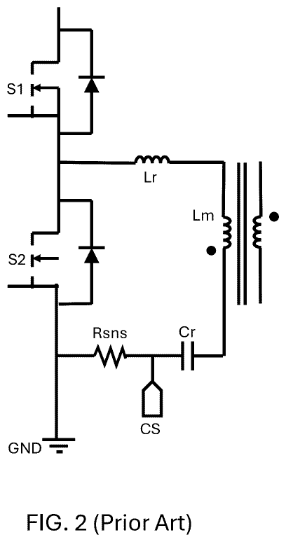

That is, in comparison to traditional current sensing structures used in the prior art, the single sensor resistor (such as Rsns of FIGS. 1 to 3) may split into two sensor resistors 409a and 409b and the resistor voltages may be combined through configuration resistors 411a and 411b.

The first configuration resistor 411a and the second sensor resistor 409b may be connected in series. The first configuration resistor 411a and the second sensor resistor 409b may additionally be connected in parallel with the second configuration resistor 411b. The first sensor resistor 409a may be connected in series with the first switch 401 and the second switch 402.

In more detail, the second sensor resistor 409b may be connected such that it is connected on one side to the first configuration resistor 411b and, on another side, may be connected to the second configuration resistor 411a and the first sensor resistor 409a. The first sensor resistor 409a may be connected such that it is connected on one side to the second switch 402 and, on another side, to the ground. A node may connect a connection between the first configuration resistor and the second sensor resistor and the connection between the first sensor resistor and the second switch 402.

The first switch 401 may be a main switch. The second switch 402 may be a reset switch.

The resonant circuit 305 may comprise an inductor (such as a resonant inductor) and a capacitor. Alternatively, the resonant circuit 305 may comprise an inductor (such as a resonant inductor) alone. Alternatively, for both of these examples, the inductor may instead be a transformer.

The current sensing circuit 400 may be configured to detect, using the plurality of resistors 309, negative over-currents by detecting if a voltage across the CS pin 407 is lower than a negative threshold. The current sensing circuit 400 may be additionally or alternatively configured to detect, using the plurality of resistors 309, positive over-currents by detecting if a voltage across the CS pin 407 is higher than a positive threshold.

When it is detected that the voltage across the CS pin is lower than the negative threshold, it may be determined that there is a negative over-current in the circuit 400 and the second switch 402 may be turned off. Similarly, when it is detected that the voltage across the CS pin is higher than the positive threshold, it may be determined that there is a positive over-current in the circuit 400 and the first switch 401 may be turned off, or both the first switch 401 and the second switch 402 may be turned off.

By turning off the second switch 402 when the current passes the negative threshold, the resonant current iLr is brought to zero and overcurrent protection is provided.

By turning off at least the first switch 401 when the current passes the positive threshold, the resonant current iLr is brought to zero and positive overcurrent protection is provided.

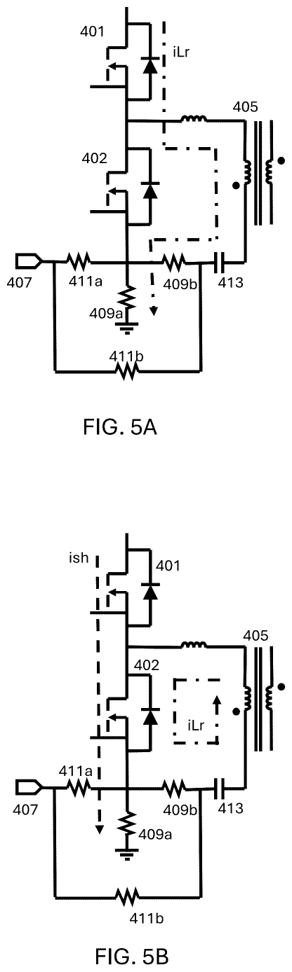

Discussing the operation mechanism in more detail, we turn now to FIGS. 5A and 5B. FIGS. 5A and 5B show an operation mechanism for the current conversion circuit such as those shown in FIGS. 3 and 4.

As shown in FIG. 5A, in normal operation, the first switch 401 is turned on and the second switch 402 is turned off, allowing current iLr to flow through the resonant circuit. Current iLr charges the capacitor 413, creating voltage Ver across the capacitor 413. If voltage Ver is large, a large resonant current iLr may in turn be generated when the second switch 402 turns on. The resonant current may be negative.

In more detail, in all conditions, a voltage at the CS pin 407 (known hereafter as V_{cs}) can be described according to equation (1):

$${V}_{cs} = {V}_{a} + k \cdot {V}_{b} \qquad ( 1 )$$

Where Vₐ is a voltage of the first sensor resistor 409a; V_{b} is a voltage of the second sensor resistor 409b; and R_{ca} and R_{cb} are resistances of the first and second configuration resistors, 411a, 411b, respectively.

Additionally, constant k may be defined according to equation (2):

$$k = \frac{{R}_{ca}}{{R}_{ca} + {R}_{cb}} \qquad ( 2 )$$

When the first switch 401 is turned on, according to FIG. 5A, the voltages of the first and second sensor resistors 409a, 409b are as follows (as shown in equations 3 and 4):

$${V}_{a} = {i}_{Lr} \cdot {R}_{a} \qquad ( 3 )$$

$${V}_{b} = {i}_{Lr} \cdot {R}_{b} \qquad ( 4 )$$

Where Rₐ is a resistance of the first sensor resistor 409a and R_{b} is a resistance of the second sensor resistor 409b.

Thus, it follows that the voltage V_{cs} must be defined according to equation 5 when the first switch 401 is turned on and the second switch 402 is turned off:

$${V}_{cs} = {i}_{Lr} \cdot ( {R}_{a} + k \cdot {R}_{b} ) \qquad ( 5 )$$

In comparison, when the first switch 401 is turned off and the second switch 402 is turned on, the voltages of the first and second sensor resistors 409a, 409b are as follows (as shown in equations 6 and 7):

$${V}_{a} = 0 \qquad ( 7 )$$

$${V}_{b} = {i}_{Lr} \cdot {R}_{b} \qquad ( 8 )$$

Thus, it follows that the voltage V_{cs} must be defined according to equation 9 when the first switch 401 is turned off and the second switch 402 is turned on:

$${V}_{cs} = {i}_{Lr} \cdot k \cdot {R}_{b} \qquad ( 9 )$$

As shown in FIG. 5B, when the second switch 402 turns on (in addition to the first switch 401), a shoot through current, ish, passes through the first switch 401 and the second switch 402 to ground, GND. This shoot through current, ish, causes a change in voltage, Va, across the first sensor resistor 409a.

Following on from equations 1 to 9 above, when both the first switch 401 and the second switch 402 are turned on, the voltages of the first and second sensor resistors 409a, 409b are as follows (as shown in equations 10 and 11):

$${V}_{a} = {i}_{sh} \cdot {R}_{a} \qquad ( 10 )$$

$${V}_{b} = {i}_{Lr} \cdot {R}_{b} \qquad ( 11 )$$

Thus, it follows that the voltage V_{cs} must be defined according to equation 12 when the first switch 401 is turned off and the second switch 402 is turned on:

$${V}_{cs} = {i}_{sh} \cdot {R}_{a} + {i}_{Lr} \cdot k \cdot {R}_{b} \qquad ( 12 )$$

Thus, the first sensor resistor 409a and the second sensor resistor 409b are used to sense the overcurrent.

In order to detect both positive and negative resonant currents and therefore provide overcurrent protection (OCP) for both positive and negative resonant currents, suitable resistor values must be selected for both sensor resistors and configuration resistors. Suitably selected resistor values also ensure that this can be achieved without adding additional CS pins.

The resistance values of the first and second configuration resistors 411a, 411b are selected to provide an effective configuration resistance for the CS pin.

In more detail, the effective sensing resistance while the first switch 401 is turned on and the second switch 402 is turned off can be described using equation (13):

$${R}_{sns \_ MS} = {R}_{a} + k \cdot {R}_{b} \qquad ( 13 )$$

Further, the effective sensing resistance while the first switch 401 is turned off and the second switch 402 is turned on can be described using equation (14):

$${R}_{sns \_ RS} = k \cdot {R}_{b} \qquad ( 14 )$$

where k is defined according to equation (2).

These equations therefore allow the selection of resistor parameters for both sensor and configuration resistors for all states of the current conversion circuit.

In more detail, the selection of appropriate resistor parameters (for both sensor and configuration resistors) may be based on selecting an appropriate value for the constant k. The constant k may be a value between 0 and 1. The constant k may be selected based on a trade-off between power loss and variations in values for shoot through current, ish. In more detail, raising the value of the constant k, reduces power loss on the second sensor resistor 409b; and lowering the value of the constant k, reduces variation in values of the shoot through current, ish. For example, if the value of the constant k was selected to be 0.9, the power loss on the second sensor resistor 409b would be small.

When selecting a ratio of resistance values of the first sensor resistor 409a and the second sensor resistor 409b, the resistance value of the second sensor resistor 409b may be selected as a portion of the resistance value of the first sensor resistor 409a (for example, R_{b}= 1/10 R_{A}). That is, with careful selection of the value of the constant k, the resistance value of the second resistor 409b may be so small that power losses are minimised. Thus, the power loss experienced in order to detect negative current when resonant current is freewheeling can be minimised.

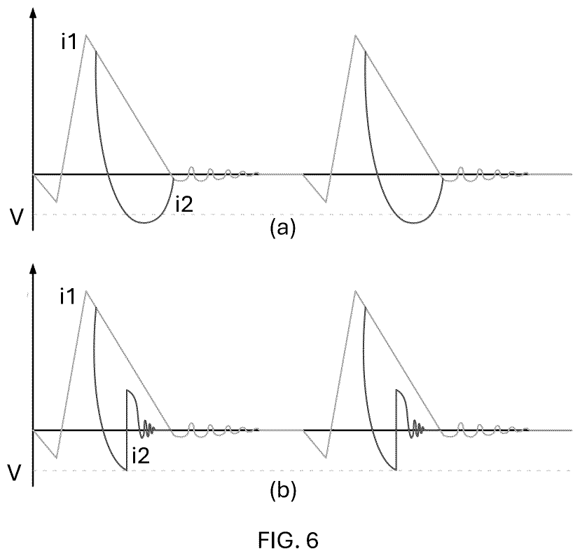

FIG. 6 shows two graphs showing waveforms representing two cycles of the resonant current for a current conversion circuit with and without the plurality of resistors represented in FIGS. 3, 4, 5A, and 5B.

Graph (a) shows two cycles of the resonant current for a current conversion circuit lacking the plurality of resistors of the current disclosure. That is, without negative resonant current overprotection.

The line labelled i2 represents the resonant current. It can be seen that the current values dip below a threshold when the resonant current is freewheeling (that is, after the second switch 402 is turned on and the voltage across the CS pin meets a threshold, as shown by the dotted line labelled “Vth”), and remain at this level and below for a significant portion of the cycle, thus allowing damage to be caused to the circuit.

In comparison, graph (b) shows the same two cycles where the overcurrent protection of the current disclosure is implemented. It can be seen that as the freewheeling resonant current reaches the threshold (that is, after the second switch 402 is turned on and the voltage across the CS pin meets the threshold, as shown by the dotted line labelled “Vth”), the overcurrent is detected and the second switch 402 is turned off, bringing the resonant current to zero and preventing damage to the circuit.

Various improvements and modifications can be made to the above without departing from the scope of the disclosure.

1. A current sensing circuit comprising:
a current sensing (CS) pin;
a first switch;
a second switch, wherein the second switch is connected between the first switch and ground;
a plurality of resistors connected between the second switch and ground; and
a resonant circuit;
wherein the plurality of resistors is configured to detect positive and/or negative over-currents in the CS pin.

2. The current sensing circuit of claim 1, wherein detecting the positive and/or negative over-currents comprises:
detecting if a voltage across the CS pin is lower than a negative threshold; and/or
detecting if a voltage across the CS pin is higher than a positive threshold.

3. The current sensing circuit of claim 2, wherein when it is detected that the voltage across the CS pin is lower than the negative threshold, it is determined that there is a negative over-current and the second switch is turned off.

4. The current sensing circuit of claim 2, wherein when a positive or negative over-current is detected, the first switch and the second switch are controlled to turn off.

5. The current sensing circuit of claim 1, wherein the resonant circuit comprises:
an inductor and a capacitor; or
an inductor.

6. The current sensing circuit of claim 1, wherein the plurality of resistors comprises:
first and second sensor resistors; and
first and second configuration resistors.

7. The current sensing circuit of claim 6, wherein a CS pin voltage, Vcs, at the CS pin is defined by:
$${V}_{cs} = {V}_{a} + k \cdot {V}_{b} ;$$
wherein Vₐ is a voltage across the first sensor resistor;
wherein Vb is voltage across the second sensor resistor;
wherein k is a ratio of resistance values of the first and second configuration resistors.

8. The current sensing circuit of claim 7, wherein when the first switch is turned on and the second switch is turned off, an effective sensing resistance for the current sensing circuit is:
$${R}_{sns \_ MS} = {R}_{a} + k \cdot {R}_{b} ;$$
wherein Rₐ is a resistance of the first sensor resistor; and
wherein R_{b} is a resistance of the second sensor resistor.

9. The current sensing circuit of claim 8, wherein when the second switch is turned on and the first switch is turned off, an effective sensing resistance for the current sensing circuit is:
$${R}_{sns \_ RS} = k \cdot {R}_{b} ;$$
wherein R_{b} is a resistance of the second sensor resistor.

10. The current sensing circuit of claim 9, wherein when the first switch is turned on and the second switch is turned off:
a first voltage across the first sensor resistor, Vₐ=i_{Lr}·Rₐ;
a second voltage across the second sensor resistor, V_{b}=i_{Lr}; and
a CS voltage across the CS pin, V_{CS}=i_{Lr}·(Rₐ+k·R_{b});
wherein i_{Lr} is an inductor current of the inductor device.

11. The current sensing circuit of claim 10, wherein when the second switch is turned on and the first switch is turned off:
the first voltage across the first sensor resistor, Vₐ=0;
the second voltage across the second sensor resistor, V_{b}=i_{Lr}·R_{b}; and
the CS voltage across the CS pin, V_{CS}=i_{Lr}·k·R_{b}.

12. The current sensing circuit of claim 11, wherein when both the second switch and the first switch are turned on:
the first voltage across the first sensor resistor, Vₐ=i_{Lr}·Rₐ;
the second voltage across the second sensor resistor, V_{b}=i_{Lr}·R_{b}; and
the CS voltage across the CS pin, V_{CS}=iₛₕ·Rₐ+i_{Lr}·k·R_{b};
wherein iₛₕ is a shoot through current passing through the first switch and the second switch.

13. The current sensing circuit of claim 12, wherein
$$k = \frac{{R}_{ca}}{{R}_{ca} + {R}_{cb}} ;$$
wherein Rca is a resistance of the first configuration resistor; and
wherein Rcb is a resistance of the second configuration resistor.

14. The current sensing circuit of claim 13, wherein k is selected based on power loss values and a shoot through current, iₛₕ, value variations.

15. The current sensing circuit of claim 6, wherein the first configuration resistor and the second sensor resistor are connected in series;
wherein the first configuration resistor and the second sensor resistor are connected in parallel with the second configuration resistor; and
wherein the first sensor resistor is connected in series with the first switch and the second switch.

16. The current sensing circuit of claim 15, wherein when the first switch and the second switch are both turned on, a current path through the first switch, the second switch, and the first sensor resistor to ground is created.

17. The current sensing circuit of claim 13, wherein resistance values of the first configuration resistor and the second configuration resistor are selected to provide an effective configuration resistance for the CS pin.

18. The current sensing circuit of claim 1, wherein the first switch is a main switch; and
wherein the second switch is a reset switch.

19. The current sensing circuit of claim 10, wherein k is a value between 0 and 1.

20. A method of operating the current sensing circuit of claim 1, the method comprising:
detecting, by the plurality of resistors, a positive and/or negative over-current in the current sensing (CS) pin.
